(19) United States
(12) Patent Application Publication
(10) Pub. No.: US 2022/0172954 A1
(43) Pub. Date: Jun. 2, 2022

(54) METHOD AND APPARATUS FOR TREATING SUBSTRATE

(71) Applicant: PSK INC., Gyeonggi-do (KR)

(72) Inventor: Hee-Woong SHIN, Gyeonggi-do (KR)

(73) Assignee: PSK INC.

(21) Appl. No.: 17/118,998

(22) Filed: Dec. 11, 2020

(30) Foreign Application Priority Data
Nov. 27, 2020 (KR) 10-2020-0161819

(51) Int. Cl. H01L 21/3065; H01J 37/32

(52) U.S. Cl. CPC H01L 21/3065; H01J 37/32357; H01J 2237/2001; H01J 37/32449; H01J 37/32724

(57) ABSTRACT

A method for processing a substrate includes removing a boron-containing thin film formed on the substrate, by supplying a processing fluid including water and alcohol into a processing space of a chamber and generating plasma from the processing fluid.

### CROSS-REFERENCE TO RELATED APPLICATIONS

A claim for priority under 35 U.S.C. § 119 is made to Korean Patent Application No. 10-2020-0161819 filed on Nov. 27, 2020, in the Korean Intellectual Property Office, the entire contents of which are hereby incorporated by reference.

### BACKGROUND

Embodiments of the inventive concept described herein relate to a method and apparatus for processing a substrate.

Plasma refers to an ionized gaseous state of matter containing ions, radicals, and electrons and is formed by very high temperature, or by application of a high electric field or an RF electromagnetic field. Semiconductor element manufacturing processes include an ashing or etching process of removing a thin film on a substrate by using plasma. The ashing or etching process is performed by allowing ions and radicals contained in plasma to collide or react with the thin film on the substrate.

An apparatus for processing a substrate using plasma may be used to remove a thin film on the substrate. For example, the thin film removed by the substrate processing apparatus may be a hard mask formed on the substrate. Among general hard masks, a hard mask containing an amorphous carbon material is a carbon-based material. Therefore, the hard mask may be easily removed from a substrate by a combination of dry gases, such as O₂, N₂, and the like, and may be easily released from a chamber.

However, in a case where the amorphous carbon material of the hard mask is heavily doped with boron, it is difficult to appropriately remove the added boron other than the carbon material through only the above-described dry gases. Accordingly, a process of removing boron added to a hard mask by using H₂O vapor has been proposed in US Patent Publication No. 2016/0062209.

### SUMMARY

However, the process has a limitation in improving efficiency of removing the boron added to the hard mask. Specifically, to enhance additional removal efficiency for the boron added to the hard mask, a process temperature at which a substrate is processed has to be raised, or the flow capacity of H₂O vapor has to be improved. However, there is a technical limitation in raising the process temperature and improving the flow capacity of H₂O vapor, and the extent of expected improvement is also small. Furthermore, in the case of simply raising the process temperature and improving the flow capacity of H₂O vapor, other processing factors acting on substrate processing are likely to be affected.

After many experiments, the inventor found that by-products generated in a process of removing a hard mask in a chamber of a substrate processing apparatus for removing the hard mask heavily doped with boron were not appropriately released from the chamber. Specifically, FIG. 1 is a graph obtained by analyzing the amounts of process by-products generated when a substrate having no BACL is processed by a substrate processing apparatus using plasma, and FIG. 2 is a graph obtained by analyzing the amounts of process by-products generated when a substrate having a BACL formed thereon is processed by a substrate processing apparatus using plasma.

In FIGS. 1 and 2, H₂, Ar, and H₂O are used as processing fluids, and the boron amorphous carbon layer (BACL) is an example of the hard mask heavily doped with boron. The BACL may react with H₂ to generate CH₄ and may be changed into B₂O₃. B₂O₃ may react with H₂O to generate B(OH)₃ that is a process by-product.

Comparing FIGS. 1 and 2, it can be seen that the process by-product B(OH)₃ is much more generated when the substrate processing apparatus processes the substrate having the BACL formed thereon than when the substrate processing apparatus processes the substrate (e.g., a bare silicon wafer) that has no BACL.

Furthermore, referring to FIG. 1, it can be seen that B(OH)₃ is generated even when the substrate processing apparatus processes the substrate having no BACL. In this regard, as illustrated in FIG. 3, the inventor analyzed the amount of the process by-product B(OH)₃ generated depending on types of injected processing fluids without generating plasma in the chamber of the substrate processing apparatus. In FIG. 3, the substrate having no BACL was carried into the chamber. Referring to FIG. 3, it can be seen that B(OH)₃ peaks when H₂O is injected into the chamber of the substrate processing apparatus under the conditions of Plasma Off and Vapor On.

Referring to FIGS. 1 to 3 together, it can be seen that when the BACL is removed from the substrate with H₂O as a processing fluid, the process by-product B(OH)₃ is generated and B₂O₃ or B(OH)₃ remains in the space of the chamber. Furthermore, it can be inferred that the process by-product B(OH)₃ generated by the reaction of B₂O₃ with H₂O is not appropriately removed from the substrate because the process by-product B(OH)₃ has relatively high boiling and melting points. Moreover, it can be inferred that in a case of a hard mask containing an amorphous carbon material heavily doped with boron, it takes more time to remove the added boron other than the carbon material.

Embodiments of the inventive concept provide a substrate processing method and apparatus for effectively removing a thin film (e.g., a hard mask) formed on a substrate, minimizing a process by-product remaining in a processing space of a chamber, and effectively releasing the process by-product remaining in the processing space of the chamber.

The technical problems to be solved by the inventive concept are not limited to the aforementioned problems, and any other technical problems not mentioned herein will be clearly understood from this specification and the accompanying drawings by those skilled in the art to which the inventive concept pertains.

According to an exemplary embodiment, a method for processing a substrate includes removing a boron-containing thin film formed on the substrate, by supplying a processing fluid including water and alcohol into a processing space of a chamber and generating plasma from the processing fluid.

According to an embodiment, the thin film may be a boron amorphous carbon layer (BACL), and the alcohol may be methanol (MeOH) or ethanol (EtOH).

According to an embodiment, the processing fluid including the water and the alcohol in a liquid phase may be vaporized in a vaporizer disposed outside the chamber and may be injected into the processing space.

According to an embodiment, the substrate may be carried into the processing space in a state in which a pattern is formed on the substrate, and the pattern may include the thin film.

According to an embodiment, the thin film may be a hard mask.

According to an embodiment, the processing space may be evacuated by an exhaust unit while, before, or after the substrate is processed.

According to an exemplary embodiment, an apparatus for removing a boron-containing thin film formed on a substrate includes a chamber having a processing space inside, a chuck that supports the substrate in the processing space, a baffle disposed over the chuck, a fluid supply unit that supplies a processing fluid including vaporized water and alcohol into the processing space, and a high-frequency power supply that is connected with at least one of the chuck or the baffle and that generates plasma from the processing fluid.

According to an embodiment, the fluid supply unit may include a vaporizer, a first processing fluid supply source that supplies water to the vaporizer, and a second processing fluid supply source that supplies alcohol to the vaporizer.

According to an embodiment, the thin film may be a boron amorphous carbon layer (BACL), and the alcohol supplied by the second processing fluid supply source may be methanol (MeOH) or ethanol (EtOH).

According to an embodiment, the apparatus may further include an exhaust unit that releases an impurity and/or the processing fluid remaining in the processing space.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a graph obtained by analyzing the amounts of process by-products generated when a substrate having no BACL is processed by a substrate processing apparatus using plasma;

FIG. 2 is a graph obtained by analyzing the amounts of process by-products generated when a substrate having a BACL formed thereon is processed by a substrate processing apparatus using plasma;

FIG. 3 is a graph obtained by analyzing the amount of a process by-product generated depending on types of processing fluids injected into a chamber of a substrate processing apparatus;

FIG. 4 is a view illustrating a substrate processed by a substrate processing apparatus according to an embodiment of the inventive concept;

FIG. 5 is a view illustrating the substrate processing apparatus according to the embodiment of the inventive concept;

FIG. 6 is a view illustrating a processing mechanism of a substrate processed by the substrate processing apparatus of FIG. 5;

FIG. 7 is a view illustrating the structural formula of a process by-product generated in a process of processing a substrate;

FIG. 8 is a view illustrating the structural formula of a material generated by reaction of the process by-product of FIG. 7 with methanol; and

FIG. 9 is a view illustrating the structural formula of a material generated by reaction of the process by-product of FIG. 7 with ethanol.

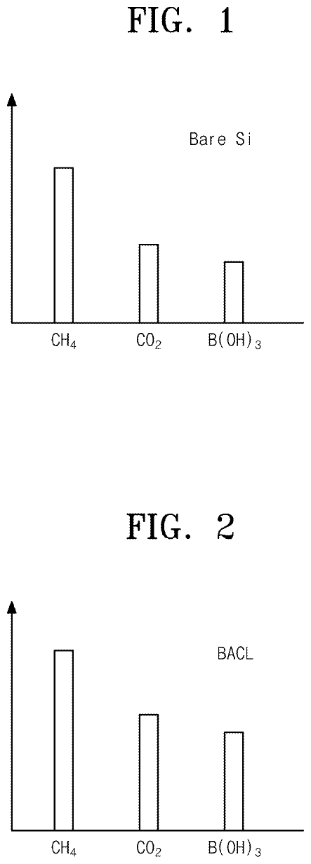

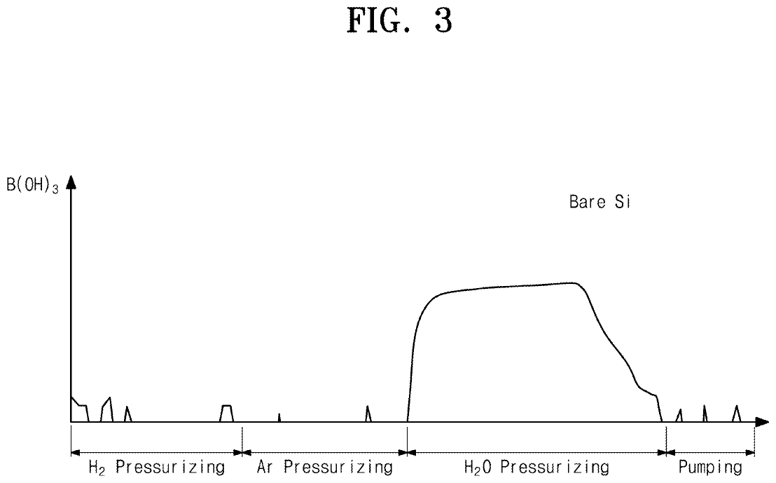

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

The terms such as first, second, and the like may be used to describe various components, but the components should not be limited by the terms. The terms may be used only for distinguishing one component from others. For example, without departing the scope of the inventive concept, a first component may be referred to as a second component, and similarly, the second component may also be referred to as the first component.

It will be understood that when a component is referred to as being “connected” or “coupled” to another component, it can be directly connected or coupled to the other component or intervening components may be present. In contrast, when a component is referred to as being “directly connected” or “directly coupled” to another component, there are no intervening components present. Other words used to describe the relationship between components should be interpreted in a like fashion (i.e., “between” versus “directly between,” “adjacent” versus “directly adjacent,” etc.).

In describing the components of the embodiment according to the inventive concept, terms such as first, second, “A”, “B”, (a), (b), and the like may be used. These terms are merely intended to distinguish one component from another component, and the terms do not limit the nature, sequence or order of the components. Unless otherwise defined, all terms used herein, including technical or scientific terms, have the same meanings as those generally understood by those skilled in the art to which the inventive concept pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

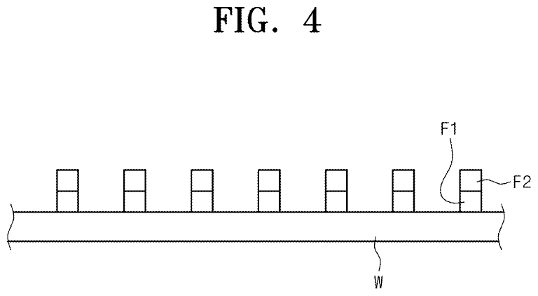

Hereinafter, embodiments of the inventive concept will be described in detail with reference to FIGS. 4 to 9.

FIG. 4 is a view illustrating a substrate processed by a substrate processing apparatus according to an embodiment of the inventive concept. Referring to FIG. 4, the substrate W processed by the substrate processing apparatus 10 according to the embodiment of the inventive concept may be a silicon wafer. A first film F1 and a second film F2 may be formed on the substrate W. The first film F1 and the second film F2 may be removed by a thin-film removal process. The first film F1 and the second film F2 may form a pattern through the thin-film removal process, and the second film F2 subjected to the thin-film removal process may be referred to as a hard mask.

The second film F2 may be a boron amorphous carbon layer (BACL) containing boron. Furthermore, the second film F2 may be a boron amorphous carbon layer (BACL) heavily doped with boron. The substrate W may be carried into a processing space 102 of a chamber 100, which will be described below, in the state in which the above-described pattern is formed on the substrate W (e.g., in the state in which the above-described hard mask, which is the BACL, is provided on the substrate W). The pattern formed on the substrate W may include the second film F2.

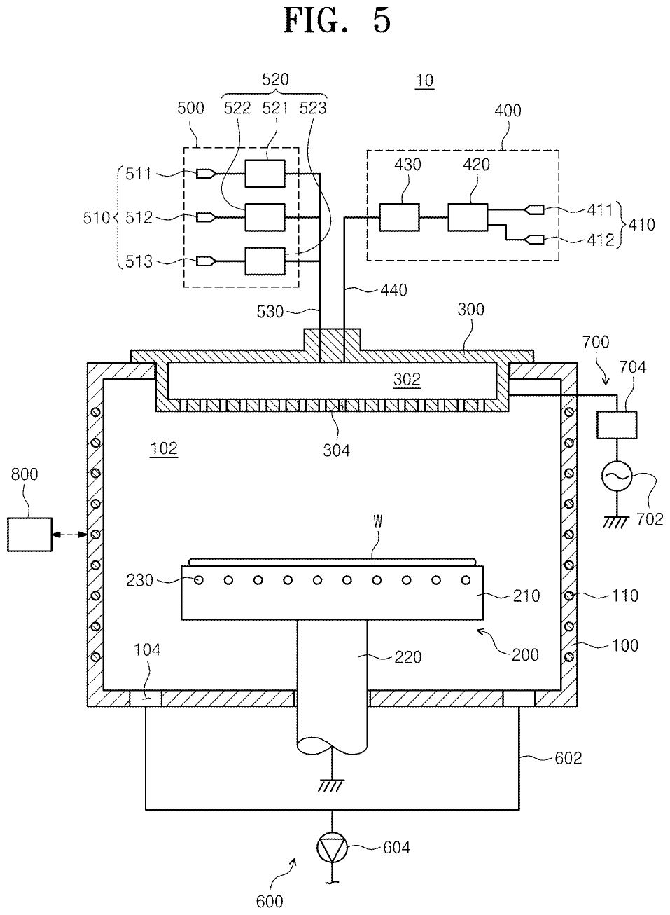

FIG. 5 is a view illustrating the substrate processing apparatus according to the embodiment of the inventive concept. Referring to FIG. 5, the substrate processing apparatus 10 according to the embodiment of the inventive concept may perform a thin-film removal process of removing the hard mask that is the second film F2 formed on the substrate W.

Referring to FIG. 5, the substrate processing apparatus 10 according to the embodiment of the inventive concept may include the chamber 100, a chuck 200, a baffle 300, a fluid supply unit 400, a gas supply unit 500, an exhaust unit 600, a power supply unit 700, and a controller 800.

The chamber 100 may have the processing space 102 inside. The chamber 100 may be grounded. The processing space 102 of the chamber 100 may be a space in which the thin-film removal process of removing the hard mask formed on the substrate W is performed. The chamber 100 may have, in a sidewall thereof, an entrance/exit opening (not illustrated) through which the substrate W is carried into or out of the processing space 102. The entrance/exit opening (not illustrated) may be selectively opened or closed by a door (not illustrated). Furthermore, the chamber 100 may have, in the bottom thereof, exhaust holes 104 connected with the exhaust unit 600 that will be described below.

In addition, the chamber 100 may be equipped with a cooling member 110. The cooling member 110 may adjust the temperature of the chamber 100. The cooling member 110 may adjust the temperature in the processing space 102. The cooling member 110 may be a fluid channel connected with a cooling fluid supply source that supplies a cooling fluid. The cooling fluid supplied to the cooling member 110 may be cooling water or cooling gas. Without being limited thereto, however, the cooling member 110 may be implemented with various well-known machinery and materials capable of transferring cold-heat to the chamber 100.

The chuck 200 may support the substrate W in the processing space 102. The chuck 200 may include a support plate 210, a lifting member 220, and a heating member 230. The support plate 210 may have a seating surface on which the substrate W is seated. The support plate 210 may have a substantially circular plate shape when viewed from above. The support plate 210 may have an electrode inside. The electrode inside the support plate 210 may be grounded.

The lifting member 220 may move the support plate 210 in an up/down direction. The lifting member 220 may change the height of the substrate W supported on the support plate 210 in the processing space 102, by moving the support plate 210 in the up/down direction.

The heating member 230 may be provided inside the support plate 210. The heating member 230 may be a heater. The heating member 230 may be a heater that is heated by electric power transmitted from a heating power supply (not illustrated). The heating member 230 may adjust the temperature of the substrate W supported on the support plate 210, by receiving electric power from the heating power supply.

The baffle 300 may supply a process gas and/or a processing fluid into the processing space 102. The baffle 300 may have a container shape with an interior space 302. The baffle 300 may have, in a lower surface thereof, injection holes 304 through which the process gas and/or the processing fluid flows. The baffle 300 may have, at the top thereof, an inlet port to which a fluid supply line 440 and a gas supply line 530, which will be described below, are connected. The processing fluid supplied by the fluid supply line 440 and the process gas supplied by the gas supply line 530 may be introduced into the interior space 302 through the inlet port. The process gas and/or the processing fluid introduced into the interior space 302 may flow into the processing space 102 through the injection holes 304. The lower surface of the baffle 300 may have a stepped shape in which a central region is in a lower position than a peripheral region. Accordingly, the baffle 300 may be inserted into an opening formed in the top of the chamber 100. Furthermore, the baffle 300 may be grounded.

The fluid supply unit 400 may supply the processing fluid into the processing space 102. The processing fluid supplied by the fluid supply unit 400 may include water (H₂O), alcohol, or the like. The alcohol may be methanol (MeOH, one example of first alcohol) or ethanol (EtOH, one example of second alcohol). The fluid supply unit 400 may include a processing fluid supply source 410, a vaporizer 420, a flow-rate adjustment member 430, and the fluid supply line 440.

The processing fluid supply source 410 may include a first processing fluid supply source 411 and a second processing fluid supply source 412. The first processing fluid supply source 411 may deliver a processing fluid including water (H₂O) to the vaporizer 420. The second processing fluid supply source 412 may deliver a processing fluid including alcohol to the vaporizer 420. The alcohol delivered to the vaporizer 420 by the second processing fluid supply source 412 may be methanol (MeOH) or ethanol (EtOH).

The processing fluid supply source 410 may deliver a processing fluid in a liquid phase to the vaporizer 420. The vaporizer 420 may change the processing fluid into a vaporized state by heating the delivered processing fluid to a high temperature. The high-temperature processing fluid changed into the vaporized state in the vaporizer 420 may be delivered to the baffle 300 through the fluid supply line 440 connected with the baffle 300. The processing fluid delivered to the baffle 300 may be injected into the processing space 102 through the injection holes 304. The flow-rate adjustment member 430 may change the supply flow-rate per unit time of the processing fluid that is delivered to the baffle 300. The flow-rate adjustment member 430 may be a regulator or a flow control valve. Without being limited thereto, however, the flow-rate adjustment member 430 may be implemented with various well-known devices capable of changing the supply flow-rate per unit time of the processing fluid.

The gas supply unit 500 may supply the process gas into the processing space 102. The process gas supplied into the processing space 102 by the gas supply unit 500 may include at least one of N₂, Ar, H₂, O₂, or O*.

The gas supply unit 500 may include a gas supply source 510, a flow-rate control member 520, and the gas supply line 530.

The gas supply source 510 may supply the process gas into the baffle 300 through the gas supply line 530. The process gas supplied into the baffle 300 may be supplied into the processing space 102 through the injection holes 304. The gas supply source 510 may include a first gas supply source 511, a second gas supply source 512, and a third gas supply source 513. The first gas supply source 511 may supply nitrogen (N₂) gas. The second gas supply source 512 may supply argon (Ar) gas. The third gas supply source 513 may supply hydrogen (H₂) gas. The supply flow-rate per unit time of the process gas supplied by the gas supply source 510 may be adjusted by the flow-rate control member 520. For example, the flow-rate control member 520 may include a first flow-rate control member 521, a second flow-rate control member 522, and a third flow-rate control member 523. The supply flow-rate per unit time of the nitrogen gas supplied by the first gas supply source 511 may be adjusted by the first flow-rate control member 521 installed on the gas supply line 530. The supply flow-rate per unit time of the argon gas supplied by the second gas supply source 512 may be adjusted by the second flow-rate control member 522 installed on the gas supply line 530. The supply flow-rate per unit time of the hydrogen gas supplied by the third gas supply source 513 may be adjusted by the third flow-rate control member 523 installed on the gas supply line 530. The flow-rate control member 520 may be a regulator or a flow-rate control valve. Without being limited thereto, however, the flow-rate control member 520 may be implemented with various well-known devices capable of adjusting the supply flow-rate per unit time of the process gas.

The exhaust unit 600 may evacuate the processing space 102. The exhaust unit 600 may evacuate the processing space 102 before, after, and/or while the substrate W is processed. By evacuating the processing space 102, the exhaust unit 600 may release, to the outside of the processing space 102, the process gas and the processing fluid supplied into the processing space 102 and by-products (or impurities) generated in a process of processing the substrate W. The exhaust unit 600 may include an exhaust line 602 connected with the exhaust holes 104 and an exhaust member 604 for applying reduced pressure to the exhaust line 602. The exhaust member 604 may be a pump. Without being limited thereto, however, the exhaust member 604 may be implemented with various well-known devices capable of evacuating the processing space 102 by applying reduced pressure to the processing space 102.

The power supply unit 700 may generate an electric field in the processing space 102. By generating the electric field in the processing space 102, the power supply unit 700 may generate plasma from the process gas or the processing fluid supplied into the processing space 102. The power supply unit 700 may include a high-frequency power supply 702 and a matcher 704. The high-frequency power supply 702 may be an RF power supply. The matcher 704 may perform matching on the high-frequency power supply 702.

The controller 800 may control the substrate processing apparatus 10. The controller 800 may control the substrate processing apparatus 10 such that the substrate processing apparatus 10 performs a thin-film removal process of removing a thin film on the substrate W. For example, the controller 800 may control at least one of the cooling member 110, the lifting member 220, the heating member 230, the heating power supply for transmitting electric power to the heating member 230, the fluid supply unit 400, the gas supply unit 500, the exhaust unit 600, or the power supply unit 700. The controller 800 may be equipped with a process controller, a user interface, and a memory unit. The process controller may include a microprocessor (a computer) that executes the control of the substrate processing apparatus 10. The user interface may include a keyboard through which an operator inputs a command to manage the substrate processing apparatus 10 or a display that visually displays an operational state of the substrate processing apparatus 10. The memory unit may store a processing recipe, such as a control program for executing a process performed in the substrate processing apparatus 10 under the control of the process controller or a program for causing each component to execute a process according to various types of data and process conditions. The user interface and the memory unit may be connected to the process controller. The processing recipe may be stored in a storage medium of the memory unit. The storage medium may be a hard disk, a portable disk, such as CD-ROM, DVD, or the like, or a semiconductor memory, such as a flash memory, or the like.

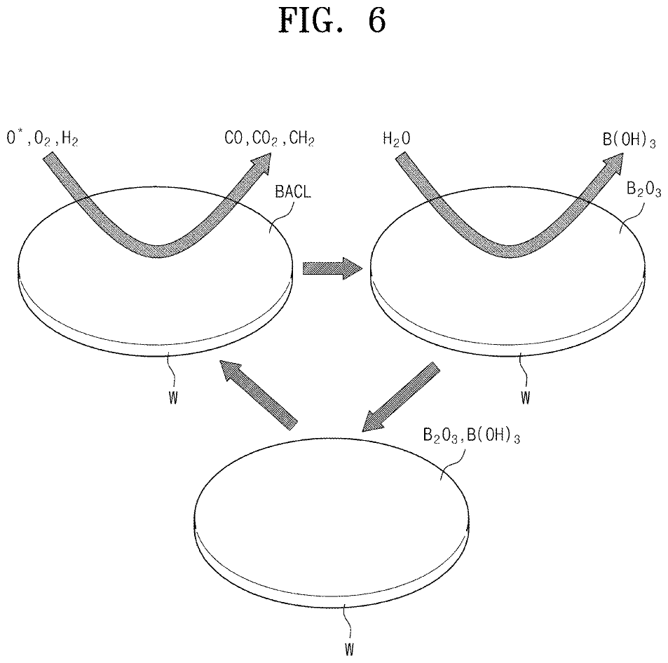

FIG. 6 is a view illustrating a processing mechanism of a substrate processed by the substrate processing apparatus of FIG. 5. Specifically, FIG. 6 is a view illustrating a mechanism by which a thin film (e.g., a BACL) formed on the substrate W is removed. Referring to FIG. 6, the substrate W may be carried into the processing space 102 in the state in which the second film F2, which is the BACL, is provided on the substrate W. The BACL on the substrate W may react with a process gas (e.g., O*, O₂, or H₂) supplied by the gas supply unit 500 and may generate a first process by-product mainly containing CO, CO₂, and CH₄. After the reaction of the BACL with the process gas supplied by the gas supply unit 500, solid boron oxide (B₂O₃) may remain on the substrate W. The solid boron oxide (B₂O₃) may react with water (H₂O) supplied by the fluid supply unit 400 and may generate a second process by-product mainly containing B(OH)₃. The above-described processing mechanism may be continuously, simultaneously, and repeatedly performed.

In a case where the fluid supply unit 400 and the gas supply unit 500 supply only O*, O₂, or H₂ and H₂O into the processing space 102, the second process by-product (boric acid) may not be appropriately removed from the substrate W, or may remain in the processing space 102 of the chamber 100. This is because the second process by-product has relatively high boiling and melting points at atmospheric pressure and the solubility of the second process by-product in water is relatively low.

Specifically, B(OH)₃ that the second process by-product mainly contains has a boiling point of 300° C. and a melting point of 171° C. That is, the second process by-product is a material that exists in a solid state at atmospheric pressure and is very difficult to vaporize. Therefore, it is difficult to remove the second process by-product from the substrate W or the processing space 102 only by simple evacuation of the exhaust unit 600. Furthermore, B(OH)₃ that the second process by-product mainly contains has a solubility of about 5.7 g/100 ml in water at 25° C. That is, the solubility of the second process by-product in water (H₂O) is relatively low, and therefore it is difficult to remove the second process by-product from the substrate W or the processing space 102.

Accordingly, a substrate processing method according to an embodiment of the inventive concept may address the above-described problems by injecting alcohol (e.g., methanol or ethanol) into the processing space 102. For example, when alcohol is injected into the processing space 102, the alcohol may generate a volatile borate by inducing esterification of the second process by-product mainly containing B(OH)₃. The volatile borate may be easily removed from the substrate W or the processing space 102.

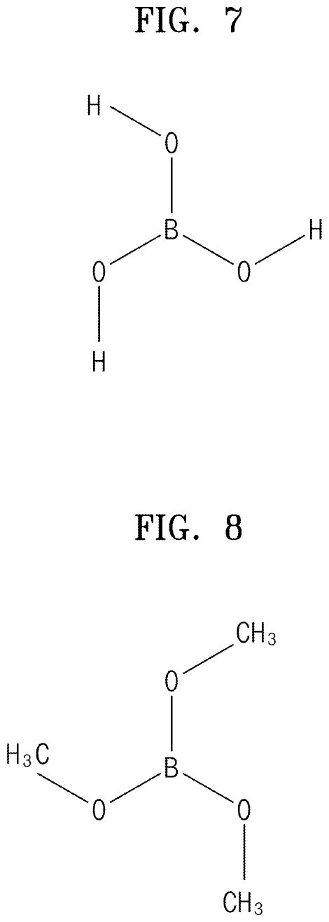

For example, B(OH)₃ that the second process by-product mainly contains has a structural formula as illustrated in FIG. 7. The equation for reaction of B(OH)₃ with alcohol is as follows.

B(OH)₃+3ROH⇔B(OR)₃+3H₂O

In a case where R is a methyl group, the name of an ester is trimethyl borate, and the structural formula of the ester is as illustrated in FIG. 8. The trimethyl borate has relatively low boiling and melting points at atmospheric pressure. Specifically, the trimethyl borate has a boiling point of 69° C. and a melting point of −34° C. That is, it can be seen that the trimethyl borate exists in a liquid state at atmospheric pressure and is easy to vaporize, compared to B(OH)₃ having a boiling point of 300° C. Because the trimethyl borate is easy to vaporize, the trimethyl borate may be easily removed from the substrate W or the processing space 102 through the exhaust unit 600 even though the temperature in the processing space 102 is slightly raised.

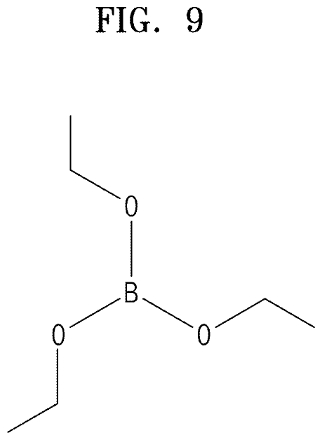

In a case where R is an ethyl group, the name of an ester is triethyl borate, and the structural formula of the ester is as illustrated in FIG. 9. The triethyl borate has relatively low boiling and melting points at atmospheric pressure. Specifically, the triethyl borate has a boiling point of 118° C. and a melting point of −85° C. That is, it can be seen that the triethyl borate exists in a liquid state at atmospheric pressure and is very easy to vaporize, compared to B(OH)₃ having a boiling point of 300° C. Because the triethyl borate is easy to vaporize, the triethyl borate may be removed from the substrate W or the processing space 102 through the exhaust unit 600 even though the temperature in the processing space 102 is slightly raised.

Furthermore, B(OH)₃ has a higher solubility in methanol or ethanol than in water. For example, the solubility of B(OH)₃ in ethanol at 25° C. is 9.4 g/100 ml that is 1.6 times greater than the solubility of B(OH)₃ in water at 25° C., and the solubility of B(OH)₃ in methanol at 25° C. is 17.4 g/100 ml that is 3.1 times greater than the solubility of B(OH)₃ in water at 25° C. That is, alcohol injected into the processing space 102 may dissolve B(OH)₃, and the alcohol having B(OH)₃ dissolved therein may be easily removed from the substrate W or the processing space 102 through the exhaust unit 600.

That is, in the method of processing the substrate by the substrate processing apparatus according to the embodiment of the inventive concept, the solubility of the second process by-product containing B(OH)₃, which is generated in the process of removing the BACL, may be increased by injecting alcohol into the processing space 102. The alcohol having B(OH)₃ dissolved therein may be easily removed from the substrate W or the processing space 102. Furthermore, the alcohol injected into the processing space 102 may induce esterification of the second process by-product containing B(OH)₃ that is generated in the process of removing the BACL. Accordingly, a highly volatile borate may be generated, and the highly volatile borate may be easily removed from the substrate W or the processing space 102. Thus, according to the embodiment of the inventive concept, the thin film (e.g., a hard mask) formed on the substrate may be effectively removed. Furthermore, according to the embodiment of the inventive concept, the process by-product remaining in the processing space of the chamber may be minimized. Moreover, according to the embodiment of the inventive concept, the process by-product remaining in the processing space of the chamber may be effectively released. In addition, according to the embodiment of the inventive concept, the substrate may be efficiently processed.

As described above, according to the embodiment of the inventive concept, a substrate may be efficiently processed.

Furthermore, according to the embodiment of the inventive concept, a thin film (e.g., a hard mask) formed on a substrate may be effectively removed.

Moreover, according to the embodiment of the inventive concept, a process by-product remaining in a processing space of a chamber may be minimized.

In addition, according to the embodiment of the inventive concept, the process by-product remaining in the processing space of the chamber may be effectively released.

Effects of the inventive concept are not limited to the aforementioned effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. A method for processing a substrate, the method comprising:
removing a boron-containing thin film formed on the substrate, by supplying a processing fluid including water and alcohol into a processing space of a chamber and generating plasma from the processing fluid, the removing including:
introducing the processing fluid into an enclosure of a baffle disposed inside the chamber through a first inlet port of the baffle; and
introducing a process gas into the enclosure of the baffle through a second inlet port of the baffle,
wherein the enclosure of the baffle includes injection holes through which the process gas and the processing fluid flow to enter the processing space, and
wherein the processing space is evacuated by an exhaust unit before or after the substrate is processed.

2. The method of claim 1, wherein the thin film is a boron amorphous carbon layer (BACL), and
wherein the alcohol is methanol (MeOH) or ethanol (EtOH).

3. The method of claim 1, wherein the processing fluid including the water and the alcohol in a liquid phase is vaporized in a vaporizer disposed outside the chamber and is injected into the processing space.

4. The method of claim 1, wherein the substrate is carried into the processing space in a state in which a pattern is formed on the substrate, and
wherein the pattern includes the thin film.

5. The method of claim 4, wherein the thin film is a hard mask.

6. (canceled)

7. An apparatus for removing a boron-containing thin film formed on a substrate, the apparatus comprising:
a chamber having a processing space inside;
a chuck configured to support the substrate in the processing space;
a baffle including an enclosure disposed inside the chamber and over the chuck;
a fluid supply unit configured to supply a processing fluid including vaporized water and alcohol into the enclosure of the baffle through a first inlet port of the baffle;
a gas supply unit configured to supply a process gas into the enclosure of the baffle through a second inlet port of the baffle;
a high-frequency power supply connected with at least one of the chuck or the baffle and configured to generate plasma from the processing fluid,
wherein the enclosure of the baffle includes injection holes through which the process gas and the processing fluid flow to enter the processing space; and
an exhaust unit configured to release an impurity and/or the processing fluid remaining in the processing space before or after the substrate is processed.

8. The apparatus of claim 7, wherein the fluid supply unit includes:
a vaporizer;
a first processing fluid supply source configured to supply water to the vaporizer; and
a second processing fluid supply source configured to supply alcohol to the vaporizer.

9. The apparatus of claim 8, wherein the thin film is a boron amorphous carbon layer (BACL), and
wherein the alcohol supplied by the second processing fluid supply source is methanol (MeOH) or ethanol (EtOH).

10. (canceled)

11. The apparatus of claim 7, wherein an entirety of the baffle is disposed on the chamber.

12. The apparatus of claim 11, wherein the process gas mixes with the processing fluid only within the enclosure of the baffle.

13. The apparatus of claim 7, wherein the high-frequency power supply is connected with the baffle to generate the plasma from the processing fluid.
